(19) United States
(12) Patent Application Publication
(10) Pub. No.: US 2015/0170915 A1
(43) Pub. Date: Jun. 18, 2015

(54) SEMICONDUCTOR STRUCTURE AND METHOD FOR MANUFACTURING THE SAME

(71) Applicant: Institute of Microelectronics, Chinese Academy of Sciences, Beijing (CN)

(72) Inventors: Jinshun Bi, Beijing (CN); Jiajun Luo, Beijing (CN); Zhengsheng Han, Beijing (CN)

(73) Assignee: Institute of Microelectroncis, Chinese Academy of Science, Beijing (CN)

(21) Appl. No.: 14/395,444

(22) PCT Filed: Sep. 21, 2012
(86) PCT No.: PCT/CN2012/081785

§ 371 Date: Jan. 30, 2015

(30) Foreign Application Priority Data
Apr. 20, 2012 (CN) 201210118939.9

(51) Int. Cl. H01L 21/02; H01L 21/84; H01L 29/10; H01L 21/033; H01L 29/423; H01L 29/06; H01L 21/266; H01L 21/265

(52) U.S. Cl. CPC H01L 21/02592; H01L 21/266; H01L 21/84; H01L 21/26506; H01L 21/0334; H01L 29/42364; H01L 29/0649; H01L 29/1033

(57) ABSTRACT

The present invention provides a method for manufacturing a semiconductor structure, which is characterized in comprising following steps: providing an SOI substrate for forming a semiconductor structure; the SOI substrate comprises a monocrystalline silicon top layer, a buried oxide layer and a support substrate; and forming an amorphous region outside the area for forming a channel region of the semiconductor structure in the monocrystalline silicon top layer. The method provided by the present invention can effectively improve reliability of a gate dielectric layer formed on the SOI substrate.

The present application claims priority benefit of Chinese patent application No. 201210118939.9, filed on 20 Apr. 2012, titled “SEMICONDUCTOR STRUCTURE AND METHOD FOR MANUFACTURING THE SAME”, which is herein incorporated by reference in its entirety.

### FIELD OF THE INVENTION

The present invention relates to semiconductor manufacturing, particularly, to a semiconductor structure and a method for manufacturing the same.

### BACKGROUND OF THE INVENTION

Silicon on insulator (Silicon-On-Insulator, SOI) technology refers to a technology of manufacturing devices and circuits on a silicon membrane of an insulating layer (a buried oxide layer BOX) and is distinguished from the conventional Bulk silicon technology, which relates to manufacturing devices and circuits directly on a semiconductor substrate, in terms of allowing all-dielectric isolation between devices. Accordingly, SOI-CMOS integrated circuits essentially avoid the latch-up effect that usually occurs in bulk silicon CMOS circuits. In addition, for SOI devices, the short-channel effect is rather small, shallow trenches are formed naturally, leakage current is rather small, and sub-threshold characteristics are quite excellent. An SOI-CMOS integrated circuit, which is characterized by no latch-up effect, high speed, low voltage of power supply, low power consumption, anti-radiation and resistance of high temperature, has a prospect of wide application.

However, a variety of impurities may result from silicon growth and subsequent manufacturing process, and these impurities would remarkably undermine the reliability of the gate dielectric layers of devices. The impurities may be divided into categories: (1) impurities gathered as the result of involvement in crystal defect extension, for example, Oxide (O), Carbon (C); (2) impurities pre-existing in crystal defect extension as the result of impurities implanting effect, for example, copper (Cu), Nickel (Ni), gold (Au), iron (Fe), etc. Metallic impurities have high mobility, which enables an extension of long distance in crystal lattice even at a moderate temperature; therefore, these impurities are more likely to flow to areas with extension defects that then absorb the impurities. Nonetheless, the electro-activeness of the extension defects of these impurities may give rise to an increase in leakage current and a decrease in breakdown voltage, which consequently result in degradation of devices.

Impurities absorbed in the defects may be removed through a method for absorbing impurities; in this way, the likelihood that impurity implantation applies to the remaining impurities is to be reduced significantly. The process of removing impurities generally comprises three steps: (1) impurities are released and dissolved in the crystal; (2) impurities disperse in the crystal; (3) impurities leave the area where devices are positioned and are absorbed by extension defects (dislocation or deposit); this prevents impurities from being released again into the active area in the subsequent step of heat treatment. Typically, transition metallic impurities are capable of rapidly, uniformly dispersing throughout the entire silicon chip. In the prior art, there are two conventional methods for removing impurities.

One method is to apply a special treatment to the back of a wafer so as to result in a damage or stress, which then in turn completes absorption of the metallic impurities. The practice such as grinding, carving or sanding, which is capable of causing mechanical damage, is able to generate a stress field at the back of the wafer; a dislocation capable of releasing the stress then arises from the process of annealing, and then the dislocation is applied to absorb impurities. However, the micro defect dots and dislocations arising from the generation of the stress field would reduce the mechanical strength of the wafer, which consequently results in an easy bend of the wafer in the process of heat treatment. In addition, it is impossible to move away the particles produced in the wafer, and it is also difficult to control the extent of damage. The damage can hardly be repaired once it has been caused.

The other method is to deposit a poly Si layer, with a thickness in the range of 1.2˜1.4 μm, at the back of a wafer. Since poly Si contains a large quantity of crystal grain boundaries and disorders of crystal lattice, which nonetheless may function as docks for capturing movable impurities. However, this method becomes nearly completely ineffective after the wafer is processed in an oxidizing environment at the temperature of 1150° C. The reason for this is that crystal grain boundaries are sharply reduced at a high temperature, and the disorders of crystal lattice are repaired when the crystal grains are reformed.

In addition, aforementioned two methods for removing impurities are not applicable to SOI structures. Due to the existence of BOX in an SOI structure, which makes it impossible for impurities and transition metallic impurities, which aggregate in crystal lattice defects in a top silicon film, to disperse into the impurity absorbing area at the back of the wafer; consequently, these impurities and transition metallic impurities aggregate inside the top silicon membrane, which ultimately undermines the reliability of the gate dielectric layer of devices. Therefore, there is an urgent need to put forward a method capable of effectively removing impurities in an SOI structure.

### SUMMARY OF THE INVENTION

The present invention aims to provide a method for manufacturing a semiconductor structure to overcome aforementioned problems.

According to one aspect of the present invention, there provides a method for manufacturing a semiconductor structure, which is characterized by comprising following steps:

a) providing a SOI substrate for forming a semiconductor structure; the SOI substrate comprises a monocrystalline silicon top layer, a buried oxide layer and a support substrate;
b) forming an amorphous region outside the area for forming a channel region of a semiconductor structure in the monocrystalline silicon top layer.

By implementing local Si ions implantation after the formation of a sacrifice layer on the surface of the SOI substrate, the method for manufacturing a semiconductor structure as provided by the present invention enables the area outside the area for forming the channel region of a semiconductor structure in the top Si film (ie, monocrystalline silicon top layer), to become a complete amorphous area. However, the buried oxide layer (BOX) cannot provide crystal seeds necessary for re-crystallization, thus re-crystallization is impossible in the vertical direction. The un-amorphozied area, in which the channel region of the semiconductor structure is to be formed, will function as crystal seeds necessary for re-crystallization, which thus enables the surrounding amorphous region to partly become monocrystalline in the horizontal direction so as to avoid leakage of devices. At the meantime, the amorphous area in the horizontal direction also functions well to absorb impurities. Thus the method effectively improves the reliability of the gate dielectric layer that is to be formed subsequently.

### BRIEF DESCRIPTION OF THE DRAWINGS

Aforesaid and/or additional characteristics and advantages of the present invention are made more evident and easily understood according to perusal of the following detailed description of exemplary embodiment(s) in conjunction with accompanying drawings, wherein:

FIG. 1 illustrates a flow chart of an embodiment of the method for manufacturing a semiconductor structure according to the present invention;

FIG. 2 to FIG. 7 illustrate cross-sectional diagrams of a semiconductor structure manufactured at respective stages according to the flowchart of the method of the present invention as shown in FIG. 1; and

FIG. 8 illustrates a diagram comparing a SOI device on which the method of the present invention is used with a SOI device on which the method of the present invention is not used, and comparing breakdown voltages on gate dielectric layers on a bulk silicon.

The same or similar reference signs in the drawings denote same or similar elements.

### DETAILED DESCRIPTION OF THE INVENTION

The objectives, technical solutions and advantages of the present invention are made more evident according to the following detailed description of exemplary embodiments in conjunction with the accompanying drawings.

Embodiments of the present invention are to be described here below, and the examples of the embodiments are shown in the drawings. Wherein same or similar reference signs in the drawings denote same or similar elements. It should be appreciated that the embodiments described below in conjunction with the drawings are illustrative and are provided for explaining the prevent invention only, thus shall not be interpreted as limitations to the present invention.

Various embodiments or examples are provided here below to implement different structures of the present invention. To simplify the disclosure of the present invention, description of components and arrangements of specific examples is given below. Of course, they are illustrative only and not limiting the present invention. Moreover, in the present invention, reference numbers and/or letters may be repeated in different embodiments. Such repetition is for purposes of simplification and clarity, yet does not denote any relationship between respective embodiments and/or arrangements being discussed. Furthermore, the present invention provides various examples for various processes and materials. However, it is obvious for a person of ordinary skill in the art that other processes and/or materials may be alternatively utilized. In addition, following structures where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. It should be noted that components illustrated in the drawings may not be drawn to scale. Description of conventional components, processing technology and crafts are omitted herein in order not to restrict the present invention unnecessarily.

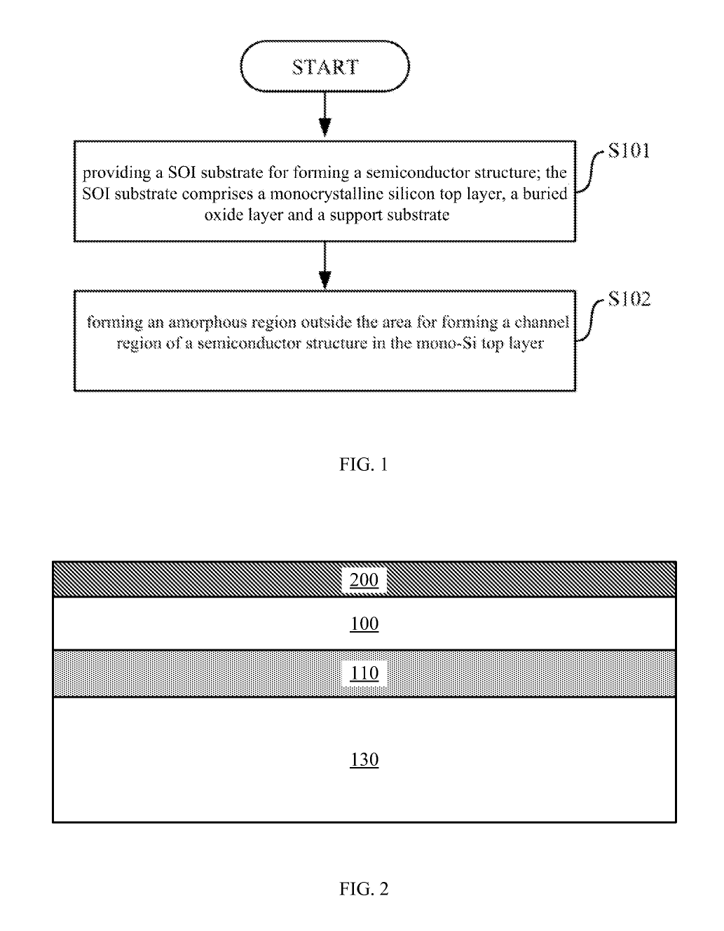

Turn to refer to FIG. 1. FIG. 1 illustrates a flow chart of an embodiment of the method for manufacturing a semiconductor structure according to the present invention. The method comprises:

step S101, providing an SOI substrate on which a semiconductor structure is to be formed; the SOI substrate comprises a monocrystalline silicon top layer, a buried oxide layer and a support substrate;

step S102, forming an amorphous region in an area outside the area for forming a channel region of a semiconductor structure.

Here below, steps S101 and S102 are to be described in conjunction with FIG. 2 to FIG. 7, which illustrate cross-sectional diagrams of a semiconductor structure manufactured at respective stages according to the flowchart of the method of the present invention as shown in FIG. 1. It should be noted that the drawings for each embodiment are provided for the mere purpose of illustration and accordingly are not drawn to scale.

Step S101 is performed to provide an SOI substrate on which a semiconductor structure is to be formed; the SOI substrate comprises a monocrystalline silicon top layer 100, a buried oxide layer 110 and a support substrate 130;

The SOI substrate at least comprises three layers, which are: the support substrate 130 (FIG. 2 only illustrates part of the supporting substrate 130), the buried oxide layer 110 on the support substrate 130, and the monocrystalline silicon top layer 100 covering the buried oxide layer 110. Wherein, the material for the buried oxide layer 110 is typically SiO₂; the thickness of the buried oxide layer 110 is usually greater than 100 nm; the material for the monocrystalline silicon top layer 100 may be monocrystalline silicon, Ge or III-IV group compound (e.g., SiC, GaAs, InAs, InP); the thickness of the monocrystalline silicon top layer 100 selected in the present embodiment is 10 nm˜10 μm, for example, 10 nm, 50 nm or 10 μm.

Next, step S102 is performed to form an amorphous region in the area outside the area for forming a channel region of a semiconductor structure.

At first, as shown in FIG. 2, a sacrifice layer 200 is formed on the monocrystalline silicon top layer. The sacrifice layer 200 is formed on the monocrystalline silicon top layer 100, with a thickness in the range of 20 nm˜200 nm, for example: 20 nm, 110 nm or 100 nm. The material for the sacrifice layer 200 is an oxide.

Next, optionally, a patterned implantation mask layer 300 is formed on the sacrifice layer 200; the implantation mask layer 300 at least covers the area for forming the channel region of the semiconductor structure.

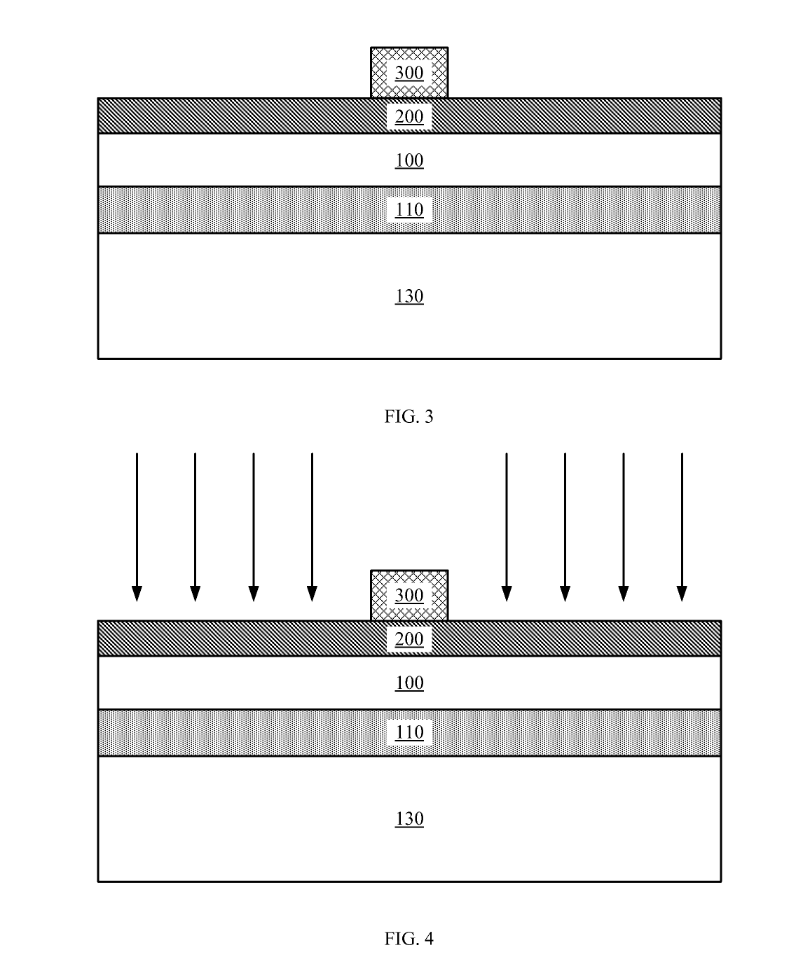

The implantation mask layer 300 is formed on the sacrifice layer 200. The material for the implantation mask layer 300 can be a material selected from a group consisting of photoresist, organic polymers, SiO₂, Si₃N₄, BSG, BPSG, and combinations thereof. Where the material for the implantation mask layer 300 is photoresist, the implantation mask layer 300 may be formed on the sacrifice layer 200 by means of spin coating or spraying, and it may be patterned through exposure and development. Where the material for the implantation mask layer 300 is an organic polymer, the implantation mask layer 300 may be formed on the sacrifice layer 200 by means of spin coating or evaporation. Where the material for the implantation mask layer 300 is any one of SiO₂, Si₃N₄, BSG and BPSG, the implantation mask layer 300 may be formed on the sacrifice layer 200 by means of chemical vapor deposition, sputtering, or any other process as appropriate. Then photoresist is deposited as a mask and patterned by means of dry etching or wet etching, as shown in FIG. 3.

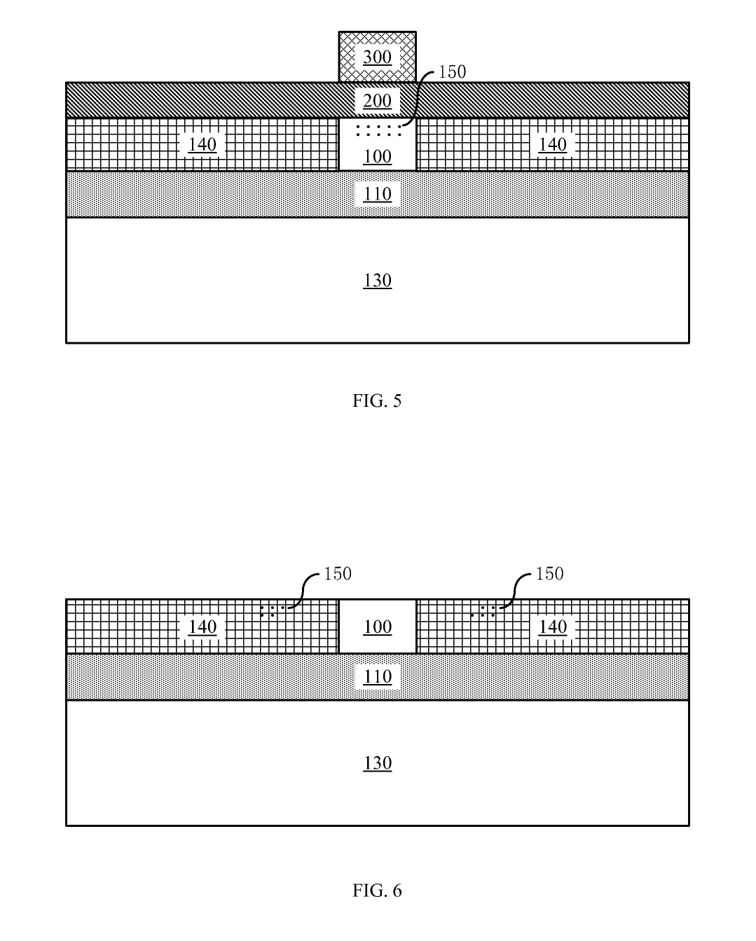

Then, Si ion implantation is performed to form an amorphous region in an area, which has not been covered by the implantation mask layer 300, in the monocrystalline silicon top layer 100. Si ion implantation is performed to the monocrystalline silicon top layer 100 of the SOI substrate. In the present embodiment, the energy of Si ion implantation is 50˜300 keV, and the implantation dose is 1E15-5E15/cm². The depth of ion implantation can be precisely controlled through implementing the process of Si ion implantation. The monocrystalline silicon top layer 100 in the Si implantation region can be amorphorized completely by implanting Si ions into the monocrystalline silicon top layer 100, so as to form an amorphous region 140; wherein there are metallic impurities 150 in the channel region, as shown in FIG. 5.

After implementation of Si ion implantation, the sacrifice layer 200 may be removed, as shown in FIG. 6. FIG. 6 further shows that the metallic impurities in the channel region have been absorbed by the amorphous region 140.

Further, an isolation region (not shown in the drawings) may be formed in the monocrystalline silicon top layer 100 in order to segment the monocrystalline silicon top layer 100 into discrete regions for the purpose of subsequent process of forming a transistor structure; the material for the isolation region is an insulating material, which may be anyone selected from a group consisting of SiO₂, Si₃N₄ and combinations thereof. The width of the isolation region depends on design needs for the semiconductor structure.

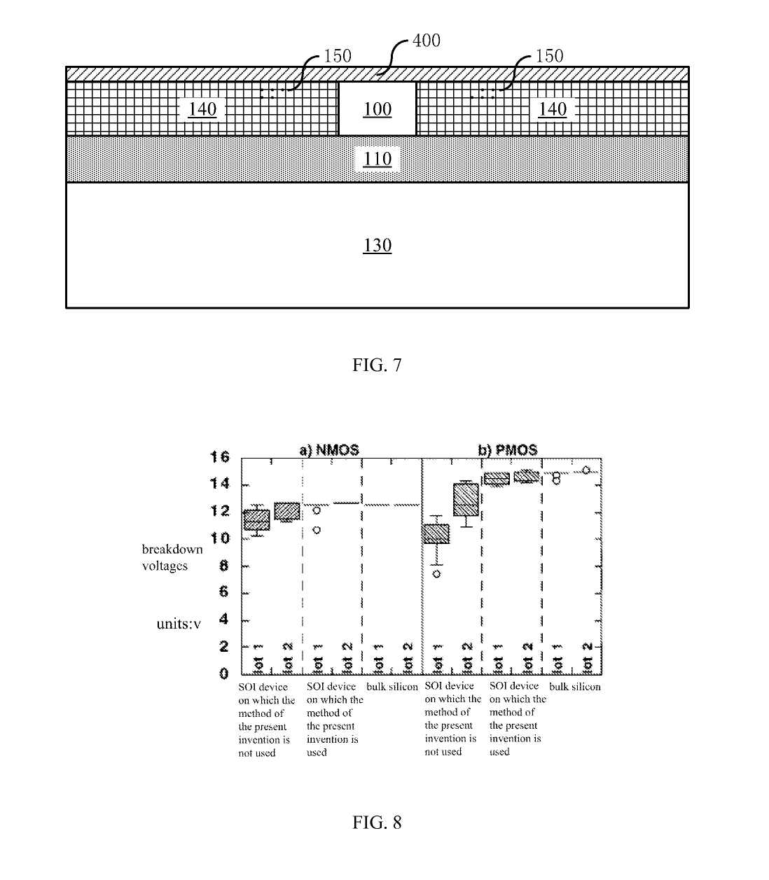

As shown in FIG. 7, a gate dielectric layer 400 is then formed on the SOI substrate. The gate dielectric layer 400 may be a thermal oxide layer, including SiO₂, Si₃N₄; alternatively, the gate dielectric layer 400 may be a high K dielectric, for example, any one selecting from the group consisting of HfAlON, HfSiAlON, HfTaAlON, HfTiAlON, HfON, HfSiON, HfTaON, HfTiON and combinations thereof. The thickness of the dielectric layer 400 may be 1 nm˜20 nm, for example, 1 nm, 5 nm or 20 nm. The dielectric layer 400 may be formed by means of thermal oxidization, Chemical Vapor Deposition (CVD), Atomic Layer Deposition (ALD) or the like. The gate dielectric layer 400 is formed at a temperature in a range of 700° C.˜1000° C., for example: 700° C., 890° C. or 1000° C.

The method of the present invention is to be explained here below in a specific embodiment.

An SOI substrate having a monocrystalline silicon top layer 100 with a thickness of 100 nm is provided, and a sacrifice layer 200 with a thickness of 150 nm is then formed on the substrate. Next, an implantation mask layer 300 is formed on the sacrifice layer 200 and then is patterned through exposure and development by means of gate photolithography. Then, Si ion implantation is implemented with an implantation dose 5E15/cm², and an implantation energy of 135˜175 keV. After the Si ion implantation, the monocrystalline silicon top layer 100 in the Si ion implantation region is completely amorphorized to form an amorphous region 140. The burial oxide layer 110 under the monocrystalline silicon top layer 100 nonetheless is unable to provide crystal seeds necessary for re-crystallization, thus re-crystallization is impossible in the vertical direction. Along with an increase in the temperature, the channel region is to serve as the crystal seed necessary for re-crystallization, such that the surrounding amorphous region 140 in the horizontal direction is partly turned into monocrystalline silicon, which therefore avoids electric leakage of the device. Meanwhile, the amorphous region 140 in the horizontal direction also displays a remarkable function of absorbing impurities. Further, the implantation mask layer 300 and the sacrifice layer 200 formed in the previous steps are removed, while the gate dielectric layer 400 with a thickness of 10.5 nm is formed on the SOI substrate at the temperature of 900° C.

The quality of the gate dielectric layer 400 may be assessed against statistics of breakdown voltage, which is defined to be a gate voltage corresponding to a current density of 300 nA/cm².

The method provided in the present invention is capable of effectively increasing the breakdown voltage of the gate dielectric layer on the SOI substrate, which means improvement of the reliability of the gate dielectric layer. As shown in FIG. 8, either in the case of an NMOS device or a PMOS device where the method of the present invention is not used, the average breakdown voltage of the gate dielectric layer on the SOI substrate in both NMOS and PMOS is significantly smaller than that where the bulk silicon technology is used. Besides, there are sharp fluctuations both within a batch and between batches. By contrast, as the method of the present invention is used, the breakdown voltage of the gate dielectric layer on the SOI substrate in both NMOS and PMOS is significantly increased, which becomes quite close to that where the bulk silicon technology is used; apart from that, there is a sharp drop in the statistical fluctuations.

Although the exemplary embodiments and their advantages have been described herein at length, it should be understood that various alternations, substitutions and modifications may be made to the embodiments without departing from the spirit of the present invention and the scope as defined by the appended claims. As for other examples, it may be easily appreciated by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a semiconductor structure comprises:
a) providing an SOI substrate for forming a semiconductor structure; the SOI substrate comprises a monocrystalline silicon top layer, a buried oxide layer and a support substrate;
b) forming an amorphous region outside the area for forming a channel regions of a semiconductor structure in the monocrystalline silicon top layer.

2. The method of claim 1, wherein the step for forming an amorphous region comprises:
forming a sacrifice layer (200) on the monocrystalline silicon top layer;
forming a patterned implantation mask layer (300) on the sacrifice layer (200), wherein the implantation mask layer (300) at least covers the region for forming the channel region for the semiconductor structure;
implementing Si ion implantation to form an amorphous region in the area, which has not been covered by the implantation mask layer (300), in the monocrystalline silicon top layer.

3. The method of claim 2 is characterized in that the thickness of the implantation mask layer (300) is 1 μm˜2 μm.

4. The method of claim 2 is characterized in that the material for the implantation mask layer (300) includes any one selected from a group consisting of photoresist, organic polymers, SiO₂, Si₃N₄, BSG, BPSG, and combinations thereof.

5. The method of claim 1 is characterized in further comprising the following step:
forming a gate dielectric layer (400) on the SW substrate.

6. The method of claim 5 is characterized in that the thickness of the gate dielectric layer (400) is 1 nm˜20 nm.

7. The method of claim 1 is characterized in that the thickness of the monocrystalline silicon top layer is 10 nm˜10 μm.

8. The method of claim 1 is characterized in that the thickness of the burial oxide layer is 20 nm˜200 nm.

9. The method of claim 2 is characterized in that the energy of the Si ion implantation is 50˜300 keV.

10. The method of claim 2 is characterized in that the dose of the Si ion implantation is 1E15˜5E15/cm².
